(19) United States
(12) Patent Application Publication
(10) Pub. No.: US 2012/0135212 A1
(43) Pub. Date: May 31, 2012

(54) COATED ARTICLE AND METHOD FOR MAKING SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); JUAN ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/207,993

(22) Filed: Aug. 11, 2011

(30) Foreign Application Priority Data
Nov. 26, 2010 (CN) 201010561039.2

(51) Int. Cl. B32B 9/04; C23C 14/08; C23C 14/06; B32B 7/02; C23C 14/34

(52) U.S. Cl. 428/216; 428/698; 428/336; 204/192.15

(57) ABSTRACT

A coated article is provided. The coated article comprises a substrate and an anti-fingerprint layer formed on the substrate. The anti-fingerprint layer comprises a plurality of aluminum oxide layers, a plurality of aluminum-nitrogen layers of aluminum-nitrogen compound, and an aluminum-oxygen-nitrogen layer of aluminum-oxygen-nitrogen compound. The aluminum oxide layers and the aluminum-nitrogen layers are alternate between the substrate and the aluminum-oxygen-nitrogen layer. A method for making the coated article is also described there.

### BACKGROUND

1. Technical Field

The present disclosure relates to coated articles, particularly to a coated article having an anti-fingerprint property and a method for making the coated article.

2. Description of Related Art

Many electronic housings are coated with an anti-fingerprint layer. These anti-fingerprint layers are usually painted on with a paint containing organic anti-fingerprint substances. However, the painted on anti-fingerprint layers usually bond weakly with metal substrates and therefore may not last very long. Furthermore, the paint may not be environmentally friendly.

Therefore, there is room for improvement within the art.

### BRIEF DESCRIPTION OF THE FIGURES

Many aspects of the coated article can be better understood with reference to the following figures. The components in the figure are not necessarily drawn to scale, the emphasis instead being placed upon clearly illustrating the principles of the coated article.

FIG. 1 is a cross-sectional view of a first exemplary embodiment of a coated article.

FIG. 2 is a cross-sectional view of a second exemplary embodiment of a coated article.

FIG. 3 is a cross-sectional view of a third exemplary embodiment of a coated article.

### DETAILED DESCRIPTION

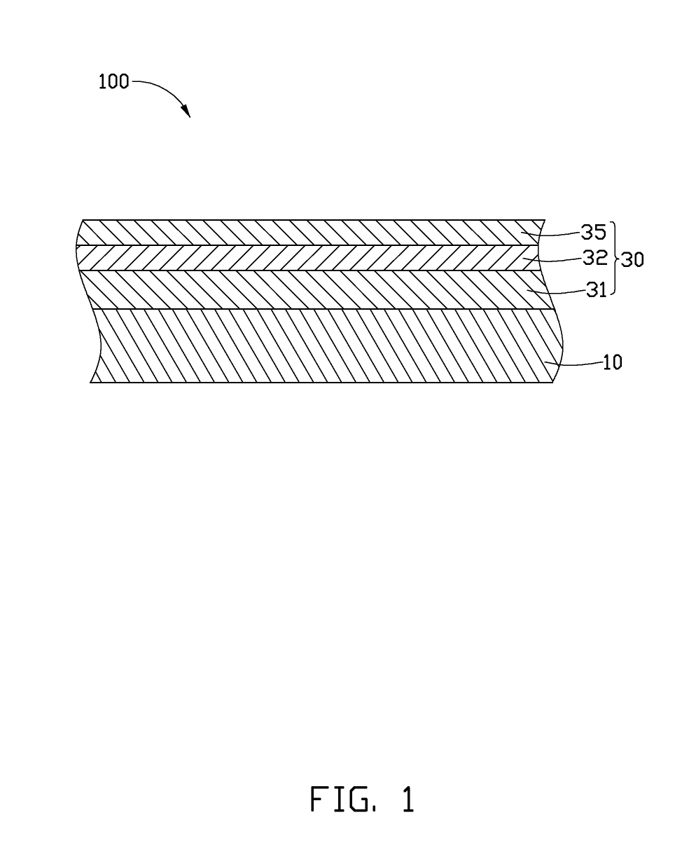

FIG. 1 shows a coated article 100 according to an exemplary embodiment. The coated article 100 may be a housing for an electronic device. The coated article 100 includes a substrate 10, and an anti-fingerprint layer 30 formed on a surface of the substrate 10.

The substrate 10 may be made of metal or non-metal material. The metal may be selected from the group consisting of stainless steel, aluminum, aluminum alloy, magnesium alloy, copper, copper alloy, and zinc. The non-metal material may be plastic, ceramic, or glass.

The anti-fingerprint layer 30 may include one or more aluminum oxide (Al₂O₃) layers, one or more aluminum-nitrogen (AlN) layers of aluminum-nitrogen compound, and an aluminum-oxygen-nitrogen (AlON) layer of aluminum-oxygen-nitrogen compound. If there are more than one layer of the Al₂O₃ layer and the AlN layer, the Al₂O₃ layer and the AlN layer will alternate with each other between the substrate 10 and the AlON layer. The anti-fingerprint layer 30 may be transparent by controlling the total thickness of the anti-fingerprint layer 30. The anti-fingerprint layer 30 may be formed by vacuum sputtering deposition, such as DC sputtering.

In a first embodiment, the anti-fingerprint layer 30 includes a first Al₂O₃ layer 31 coated on the substrate 10, a first AlN layer 32, and an AlON layer 35 coated thereon and in that order. The first Al₂O₃ layer 31 may have a thickness of about 0.2 μm-0.8 μm. The first AlN layer 32 may have a thickness of about 0.05 μm-0.2 μm. The AlON layer 35 may have a thickness of about 0.05 μm-0.1 μm.

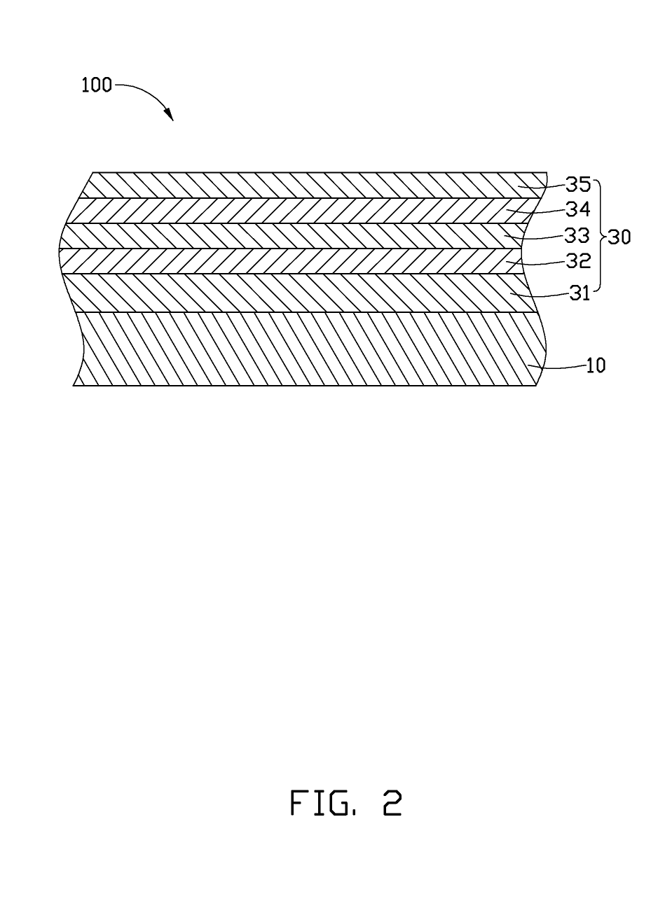

Referring to FIG. 2, in a second exemplary embodiment, the anti-fingerprint layer 30 includes a first Al₂O₃ layer 31 coated on the substrate 10, a first AlN layer 32, a second Al₂O₃ layer 33, a second AlN layer 34, and an AlON layer 35 coated thereon and in that order. The first Al₂O₃ layer 31 may have a thickness of about 0.2 μm-0.8 μm. The first AlN layer 32, second Al₂O₃ layer 33, and the second AlN layer 34 each has a thickness of about 0.05 μm-0.2 μm. The AlON layer 35 has a thickness of about 0.05 μm-0.1 μm.

The anti-fingerprint layer 30 has a good anti-fingerprint property. In addition, the incorporation of nitrogen enhances the intensity anti-fingerprint layer 30, thereby the anti-fingerprint layer 30 achieve a good erosion resistance.

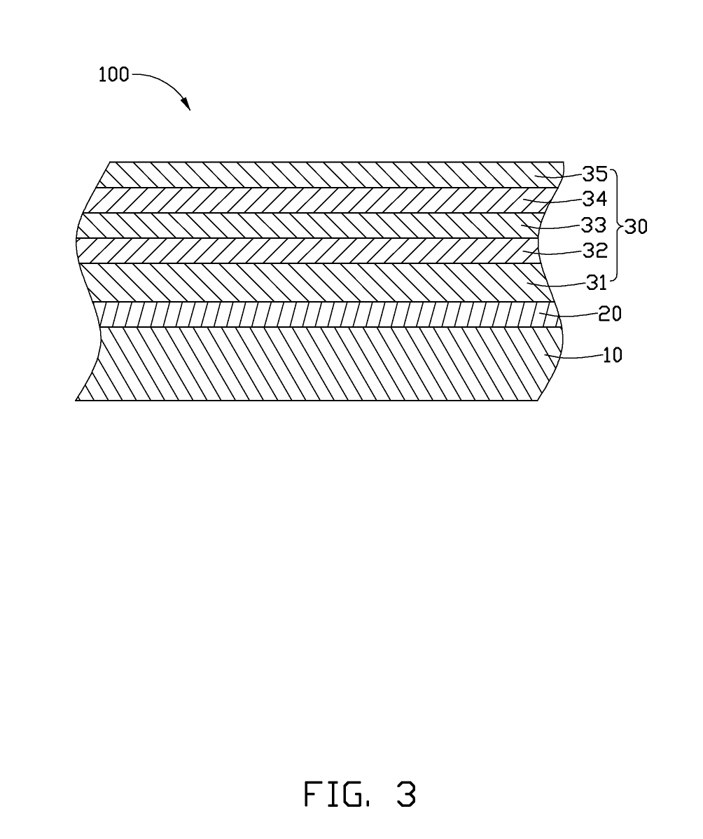

Referring to FIG. 3, in a third exemplary embodiment, the coated article 100 may further include a decorative layer 20 located between the substrate 10 and the anti-fingerprint layer 30, to provide decorative color or patterns for the coated article 100. The decorative layer 20 may be a metallic coating formed by vacuum sputtering deposition.

An exemplary method for making the coated article 100 may include the following steps:

The substrate 10 is provided.

The substrate 10 is pretreated. The substrate 10 is cleaned with a solution (e.g., alcohol or acetone) in an ultrasonic cleaner, to remove impurities such as grease or dirt from the substrate 10. Then, the substrate 10 is dried.

The substrate 10 is plasma cleaned. The substrate 10 may be positioned in a vacuum chamber of a vacuum sputtering machine (not shown). The vacuum chamber is fixed with aluminum targets therein. The vacuum chamber is then evacuated to about 8.0×10⁻³ Pa. Argon (Ar, having a purity of about 99.999%) is injected into the chamber at a flow rate of about 500 standard-state cubic centimeters per minute (sccm) to 800 sccm. A bias voltage of about −500 V to about −800 V is applied to the substrate 10. Ar is ionized to plasma. The plasma then strikes the surface of the substrate 10 to clean the surface of the substrate 10. Plasma cleaning the substrate 10 may take about 5 minutes (min) to 10 min. The plasma cleaning process enhances the bond between the substrate 10 and the anti-fingerprint layer 30. The aluminum targets are unaffected by the plasma cleaning process.

After the plasma cleaning is finished, the anti-fingerprint layer 30 is vacuum sputtered on the pretreated substrate 10. In this exemplary embodiment, the anti-fingerprint layer 30 includes a first Al₂O₃ layer 31 coated on the substrate 10, a first AlN layer 32, and an AlON layer 35. Sputtering the anti-fingerprint layer 30 may be implemented in the vacuum chamber of the vacuum sputtering machine and may be carried out in the following steps.
a). The inside of the vacuum chamber is heated to maintain a temperature of about 50° C.-300° C. Ar and oxygen (O₂) are simultaneously fed into the chamber, with the Ar acting as a sputtering gas, and the O₂ acting as a reaction gas. The flow rate of the Ar is about 200 sccm to 500 sccm. The flow rate of the O₂ is about 50 sccm-300 sccm. A bias voltage of about −50 V to about −150 V may be applied to the substrate 10. About 2 kW-5 kW of power is applied to the aluminum targets fixed in the chamber, depositing the first Al₂O₃ layer 31 on the substrate 10. The deposition of the first Al₂O₃ layer 31 may take about 60 min-240 min.
b). Then, the first AlN layer 32 is directly formed on the first Al₂O₃ layer 31 by vacuum sputtering. O₂ is stopped being fed into the chamber. Ar and nitrogen (N₂) are simultaneously fed into the chamber, with the N₂ acting as a reaction gas. The flow rate of the N₂ is about 50 sccm to 150 sccm. About 2 kW-5 kW of power is applied to the aluminum targets, depositing the first AlN layer 32. Other parameters are the same as the deposition of the first Al₂O₃ layer 31. The deposition of the first AlN layer 32 may take about 5 min-30 min.
c). The AlON layer 35 is directly formed on the first AlN layer 32 by vacuum sputtering. Ar, O₂, and N₂ are simultaneously fed into the chamber, with the O₂ and N₂ acting as reaction gases. The flow rate of the O₂ is about 50 sccm to 300 sccm. About 2 kW-5 kW of power is applied to the aluminum targets, depositing the AlON layer 35. Other parameters are the same as the deposition of the first AlN layer 32. The deposition of the AlON layer 35 may take about 5 min-30 min.

It should be understood that, before implementing the step c), the steps a) and b) may be repeated to form additional Al₂O₃ layer and additional AlN layer.

The method for making the coated article 100 may further include forming the decorative layer 20 on the substrate 10 by vacuum sputtering deposition, before sputtering the anti-fingerprint layer 30.

The anti-fingerprint property of the anti-fingerprint layer 30 has been tested by using a dyne test pen (brand: ACCU; place of production: U.S.A.). The test indicates that the surface tension of the anti-fingerprint layer 30 is below 30 dynes, thus, the anti-fingerprint layer 30 has a good anti-fingerprint property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a substrate; and
an anti-fingerprint layer formed on the substrate, the anti-fingerprint layer comprising a plurality of aluminum oxide layers, a plurality of aluminum-nitrogen layers of aluminum-nitrogen compound, and an aluminum-oxygen-nitrogen layer of aluminum-oxygen-nitrogen compound;
wherein the aluminum oxide layers and the aluminum-nitrogen layers alternate with each other between the substrate and the aluminum-oxygen-nitrogen layer.

2. The coated article as claimed in claim 1, wherein the anti-fingerprint layer is formed by vacuum sputtering deposition.

3. A coated article, comprising:
a substrate; and
an anti-fingerprint layer formed on the substrate, the anti-fingerprint layer comprising:
a first aluminum oxide layer on the substrate, the first aluminum oxide layer comprising aluminum oxide;
a first aluminum-nitrogen layer on the first aluminum oxide layer, the first aluminum-nitrogen layer comprising aluminum-nitrogen compound; and
an aluminum-oxygen-nitrogen layer on the first aluminum-nitrogen layer, the aluminum-oxygen-nitrogen layer comprising aluminum-oxygen-nitrogen compound.

4. The coated article as claimed in claim 1, wherein the anti-fingerprint layer is formed by vacuum sputtering deposition.

5. The coated article as claimed in claim 3, wherein the first aluminum oxide layer has a thickness of about 0.2 μm-0.8 μm.

6. The coated article as claimed in claim 3, wherein the first aluminum-nitrogen layer has a thickness of about 0.05 μm-0.2 μm; the aluminum-oxygen-nitrogen layer has a thickness of about 0.05 μm-0.1 μm.

7. The coated article as claimed in claim 3, further comprising a second aluminum oxide layer and a second aluminum-nitrogen layer arranged between the first aluminum-nitrogen layer and the aluminum-oxygen-nitrogen layer, with the second aluminum oxide layer adjacent to the first aluminum-nitrogen layer.

8. The coated article as claimed in claim 7, wherein the first aluminum oxide layer has a thickness of about 0.2 μm-0.8 μm.

9. The coated article as claimed in claim 3, wherein the first aluminum-nitrogen layer, the second aluminum oxide layer, and the second aluminum-nitrogen layer each has a thickness of about 0.05 μm-0.2 μm; the aluminum-oxygen-nitrogen layer has a thickness of about 0.05 μm-0.1 μm.

10. The coated article as claimed in claim 3, wherein the anti-fingerprint layer is transparent.

11. The coated article as claimed in claim 3, further comprising a decorative layer formed between the substrate and the anti-fingerprint layer.

12. A method for making a coated article, comprising:
providing a substrate;
forming an anti-fingerprint layer on the substrate by vacuum sputtering, vacuum sputtering the anti-fingerprint layer including:
vacuum sputtering a first aluminum oxide layer on the substrate, using aluminum targets and using oxygen as reaction gas, the first aluminum oxide layer comprising aluminum oxide;
vacuum sputtering a first aluminum-nitrogen layer on the first aluminum oxide layer, using aluminum targets and using nitrogen as reaction gas, the first aluminum-nitrogen layer comprising aluminum-nitrogen compound; and
vacuum sputtering an aluminum-oxygen-nitrogen layer on the first aluminum-nitrogen layer, using aluminum targets and using nitrogen and oxygen as reaction gases, the aluminum-oxygen-nitrogen layer comprising aluminum-oxygen-nitrogen compound.

13. The method as claimed in claim 12, wherein during vacuum sputtering the first aluminum oxide layer, about 2 kW to about 5 kW of power is applied to the aluminum targets; the flow rate of the oxygen is about 50 sccm to about 300 sccm; argon at a flow rate of about 200 sccm to about 500 sccm is used as a sputtering gas; a bias voltage of about −50 V to about −150 V is used to the substrate; and the sputtering temperature is about 50° C. to about 300° C.

14. The method as claimed in claim 13, wherein vacuum sputtering the first aluminum oxide layer takes about 60 min to 240 min.

15. The method as claimed in claim 12, wherein during vacuum sputtering the first aluminum-nitrogen layer, about 2 kW to about 5 kW of power is applied to the aluminum targets; the flow rate of the nitrogen is about 50 sccm to about 150 sccm; argon at a flow rate of about 200 sccm to about 500 sccm is used as a sputtering gas; a bias voltage of about −50 V to about −150 V is used to the substrate; and the sputtering temperature is about 50° C. to about 300° C.

16. The method as claimed in claim 15, wherein vacuum sputtering the first aluminum-nitrogen layer takes about 5 min to 30 min.

17. The method as claimed in claim 12, wherein during vacuum sputtering the aluminum-oxygen-nitrogen layer, about 2 kW to about 5 kW of power is applied to the aluminum targets; the flow rate of the nitrogen is about 50 sccm to about 150 sccm; the flow rate of the oxygen is about 50 sccm to 300 sccm; argon at a flow rate of about 200 sccm to about 500 sccm is used as a sputtering gas; a bias voltage of about −50 V to about −150 V is used to the substrate; and the sputtering temperature is about 50° C. to about 300° C.

18. The method as claimed in claim 17, wherein vacuum sputtering the aluminum-oxygen-nitrogen layer takes about 5 min to 30 min.

19. The method as claimed in claim 12, further comprising orderly forming a second aluminum oxide layer and an second aluminum-nitrogen layer between the first aluminum-nitrogen layer and the aluminum-oxygen-nitrogen layer by vacuum sputtering deposition, before the step of vacuum sputtering the aluminum-oxygen-nitrogen layer.
